(19) United States
(12) Patent Application Publication
(10) Pub. No.: US 2019/0181190 A1
(43) Pub. Date: Jun. 13, 2019

(54) DISPLAY DEVICE

(71) Applicant: Japan Display Inc., Tokyo (JP)

(72) Inventor: Asami SAKAMOTO, Tokyo (JP)

(21) Appl. No.: 16/207,258

(22) Filed: Dec. 3, 2018

(30) Foreign Application Priority Data
Dec. 8, 2017 (JP) 2017-235890

(51) Int. Cl. H01L 27/32; H01L 51/50

(52) U.S. Cl. CPC H01L 27/3218; H01L 51/5004; H01L 51/5088; H01L 51/5056; H01L 51/5096; H01L 51/5072; H01L 27/3216; H01L 2251/552; H01L 27/3244; H01L 51/5012

(57) ABSTRACT

A display device includes a first pixel emitting a first color and arranged with a first sub-pixel and a second sub-pixel, the first sub-pixel including a first light emitting element and a second light emitting element, a second pixel emitting a second color different from the first color and next to the first pixel, and a third pixel emitting a third color different from the first color and the second color and next to the first pixel, wherein the first light emitting element and the second light emitting element have mutually different magnitude of current density in which light emitting efficiency is at a peak.

### CROSS REFERENCE TO RELATED APPLICATIONS

This application is based upon and claims the benefit of priority from the prior Japanese Patent Application No. 2017-235890, filed on Dec. 8, 2017, the entire contents of which are incorporated herein by reference.

### FIELD

One embodiment of the present invention is related to a display device.

### BACKGROUND

Organic EL devices sometimes have low light emission efficiency in a low current density range. When a sufficient light emission efficiency cannot be obtained in a low current density range, there is a problem whereby power consumption increases. For example, when light emission at a low current density, that is, when a low luminosity image is displayed, the power necessary for light emission of the luminosity increases as the light emission efficiency decreases.

In order to solve such a problem, a technique is known in which light emission is performed in a current density region with a relatively high light emission efficiency, a black screen is inserted into a part of the light emission time period to lower the luminosity and an image is displayed with low luminosity. However, when a black screen is inserted in an environment where a display vibrates, for example, a display mounted in a vehicle, there is a problem whereby flicker occurs and image quality is lost. Therefore, it is difficult to sufficiently solve the problem described above by inserting a black screen.

Conventionally, in order to obtain a wide gradation in an organic EL display device, a means for controlling a minimum current value by making the light emission efficiency per unit current of two sub-pixels which emit light of the same emission color lower in one sub-pixel than the other sub-pixel is disclosed (for example, Japanese Laid-Open Patent Publication No. 2008-225101).

### SUMMARY

A display device in an embodiment of the present invention includes a first pixel emitting a first color and arranged with a first sub-pixel and a second sub-pixel, the first sub-pixel including a first light emitting element and a second light emitting element, a second pixel emitting a second color different from the first color and next to the first pixel, and a third pixel emitting a third color different from the first color and the second color and next to the first pixel, wherein the first light emitting element and the second light emitting element have mutually different magnitude of current density in which light emitting efficiency is at a peak.

### BRIEF DESCRIPTION OF DRAWINGS

FIG. 1 is a schematic top surface view of a display device related to a first embodiment of the present invention;

FIG. 2 is a cross-sectional view of a display device related to a first embodiment of the present invention;

FIG. 3 is a cross-sectional view of a display device related to a first embodiment of the present invention;

FIG. 4 is a schematic view of a light emitting element of a display device related to a first embodiment of the present invention;

FIG. 5 is a graph showing a relationship between light emission efficiency and current density of a light emitting element of a display device related to a first embodiment of the present invention;

FIG. 6 is a cross-sectional view of a light emitting element of a display device related to a second embodiment of the present invention;

FIG. 7 is a graph showing a relationship between light emission efficiency and current density of a light emitting element of a display device related to a second embodiment of the present invention;

FIG. 8 is a cross-sectional view of a display device related to a modified example 1 of the present invention;

FIG. 9 is a plan view showing a structure of a pixel of a display device related to a modified example 2 of the present invention; and

FIG. 10 is a plan view showing a structure of a pixel of a display device related to a modified example 3 of the present invention.

### DESCRIPTION OF EMBODIMENTS

The embodiments of the present invention are explained below while referring to the drawings. However, the present invention can be implemented in various modes and should not to be interpreted as being limited to the description of the embodiments exemplified below. Although the drawings may be schematically represented in terms of width, thickness, shape, and the like of each part as compared with their actual mode in order to make explanation clearer, it is only an example and an interpretation of the present invention is not limited. In the present specification and each drawing, the same reference numerals (or reference numerals with a, b, etc. added after the numerals) are attached to the same elements as those described above with reference to previous figures, and a detailed explanation may be omitted as appropriate. Furthermore, the characters written as “first” and “second” for each element are convenience signs used for distinguishing respective elements and do not have any further meanings unless otherwise specified.

In the present specification, in the case where certain parts or regions are given as “above” or “on” (“below” or “under”) other parts or regions, as long as there is no particular limitation, these include parts which are not only directly above (or directly below) other parts or regions but also in an upper direction (or lower direction). That is, in the case where certain parts or regions are given as “above” or “on” (“below” or “under”) other parts or regions, other structural elements may be included between other parts or regions in an upper direction (or lower direction). Furthermore, in the explanation herein, unless otherwise specified, the side on which a first film is arranged with respect to a substrate is referred to as “upper” or “above”, and the opposite side is referred to as “lower” or “below”.

### First Embodiment

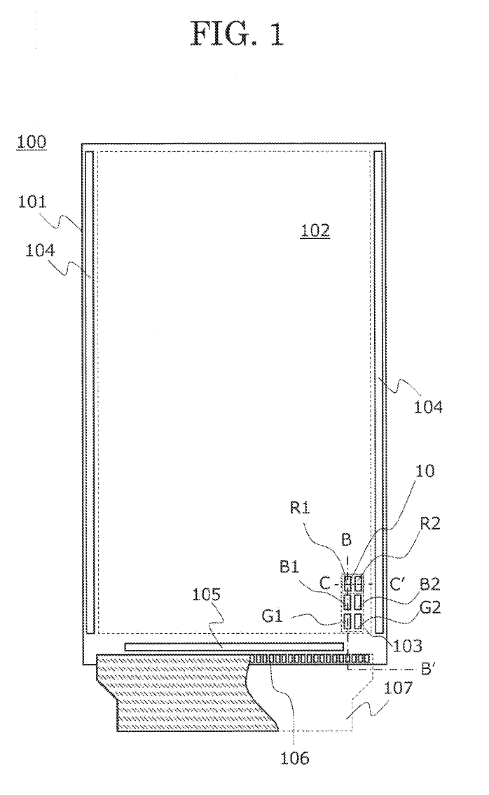

A display device 100 according to the present embodiment is explained while referring to FIG. 1 to FIG. 5.

### <Structure of Display Device>

FIG. 1 is a schematic top surface view of the display device 100 according to the first embodiment of the present invention.

The display device 100 includes a substrate 101 and has various conductive layers, semiconductor layers, insulating layers and light emitting layers which are patterned into a desired shape on one surface of the substrate. A thin film transistor (or a pixel circuit) and a light emitting element are formed by these conductive layers, semiconductor layers and insulating layers. Furthermore, a plurality of pixels 103 arranged with a thin film transistor and a light emitting element are formed. In addition, a gate drive circuit 104 (also referred to as a scanning signal drive circuit) and a source drive circuit 105 (also referred to as an image signal drive circuit) for driving the plurality of pixels 103 may be formed on the substrate 101 at the same time as a pixel circuit arranged with the plurality of pixels 103 using the conductive layer, the semiconductor layer and insulating layer mentioned above, or an IC may be mounted on one surface of the substrate 101. The plurality of pixels 103 are arranged in, for example, a matrix and a display region 102 is formed by these collections.

The gate drive circuit 104 and the source drive circuit 105 are arranged in a periphery region on the outer side of the display region 102. From the display region 102, the gate drive circuit 104 and the source drive circuit 105, various wirings (not shown in the diagram) formed by a patterned conductive layer extend to one side of the substrate 101, and each wiring is electrically connected to a terminal 106 arranged in the end vicinity of the substrate 101. These terminals 106 are connected to an FPC (Flexible Printed Circuit) 107. In the case where the drive circuits mentioned above are arranged by the IC, it may be mounted on the FPC 107 instead of the substrate 101.

An image signal and various control signals are supplied from a controller (not shown in the diagram) outside the display device via the FPC 107, and the image signal is processed by the source drive circuit 105 and input to the plurality of pixels 103. The various control signals are input to the gate drive circuit 104 and the source drive circuit 105.

In addition to an image signal and the various control signals, power for driving the gate drive circuit 104, the source drive circuit 105 and the plurality of pixels 103 is supplied to the display device 100.

Each of the plurality of pixels 103 includes a plurality of sub-pixels 10, and each of the plurality of sub-pixels 10 includes one or a plurality of light emitting elements respectively. A part of the power supplied to the display device 100 is supplied to each of the plurality of light emitting elements in order to make a light emitting element emit light.

Each of the sub-pixels 10 of the display device 100 according to the first embodiment of the present invention includes a first sub-pixel having light emitting elements R1 and R2 which emit red light, a second sub-pixel having light emitting elements G1 and G2 which emit green light, and a third sub-pixel having light emitting elements B1 and B2 which emit blue light. Although one of the first to third sub-pixels is sometimes explained below as an example, this explanation is also common to sub-pixels which emit other colors.

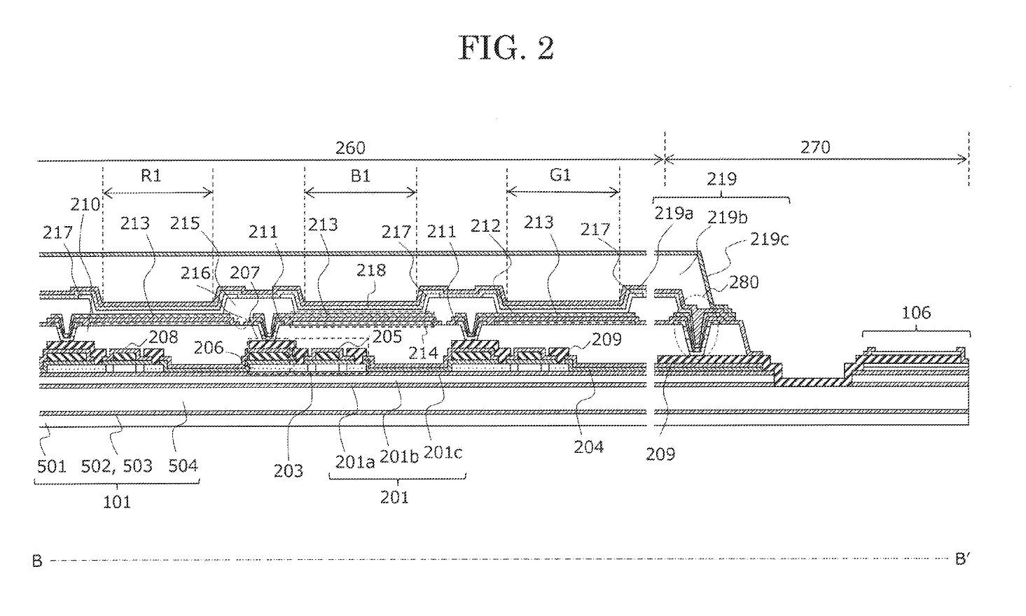

FIG. 2 is a cross-sectional view showing the display device 100 according to the first embodiment of the present invention.

FIG. 2 schematically shows the line B-B′ cross-sectional structure of the display device 100 in FIG. 1. FIG. 2 also shows a cross-sectional structure of a display region 260 and a periphery region 270. FIG. 2 mainly shows an N-channel type thin film transistor (also referred to as “TFT” herein) which form the pixel 103 (or a pixel circuit) shown in FIG. 1. In addition, the display region 260 (the display region 102 shown in FIG. 1) includes a TFT which is also referred to as “Nch TFT” in the case when it is an N-channel type, and “Pch TFT” in the case when it is a P-channel type.

A three-layer stacked structure of a silicon oxide layer 201a, a silicon nitride layer 201b and a silicon oxide layer 201c is arranged as an undercoat layer 201 on the substrate 101 which includes a stacked structure including a first resin layer 501, a first inorganic insulating layer 502, a second inorganic insulating layer 503 and a second resin layer 504. The silicon oxide layer on the lowermost layer can improve adhesion to the substrate 101. In addition, the silicon nitride layer of the middle layer can suppress the entrance of moisture and impurities from the outside. In addition, the silicon oxide layer on the uppermost layer can suppress hydrogen atoms contained in the silicon nitride layer from diffusing into the semiconductor layer 211. The undercoat layer 203 is not limited to the three-layer structure described above. Stacked layers or a single layer or two layers may be further stacked on the substrate 101.

TFTs 203 are formed above the undercoat layer 201. Polysilicon TFTs having polysilicon 206 are used as an example of the TFT 203, and although only Nch TFTs are shown here, Pch TFTs may also be formed at the same time. The polysilicon 206 is, for example, low temperature polysilicon (LTPS). The TFT 203 may be formed using an oxide semiconductor. The Nch TFT has a structure in which a low concentration impurity region is arranged between a channel region and a source/drain region. Here, a silicon oxide layer is used as the gate insulating film 204, and the gate electrode 205 is a MoW film (first wiring layer). In addition to the gate electrode 205 of the TFT 203, the first wiring layer forms a storage capacitor line and is also used for the formation of a storage capacitor (Cs) 207 between the polysilicon 206.

A silicon nitride layer or a silicon oxide layer which serves as a interlayer insulating layer 208 are each stacked on the TFT 203, patterning is then performed to form a contact hole which reaches the polysilicon 206 and the like. Furthermore, since the undercoat layer 201 is exposed by removing the interlayer insulating layer 208, this is also removed by patterning. When the undercoat layer 201 is removed, the second resin layer 504 which forms the substrate 101 is exposed. In addition, at this time, although not specifically shown in the diagram, the surface of the second resin layer 504 may be partly eroded through etching of the undercoat layer 201 which produces film loss.

Furthermore, a conductive layer (second wiring layer) 209 which serves as a source/drain electrode and a lead wiring is formed. Here, a three-layer stacked structure of Ti, Al and Ti is adopted. A part of the storage capacitor (Cs) 207 is formed by an electrode formed by a conductive layer (second wiring layer) in the same layer as the interlayer insulating layer 208 and the gate electrode 204 of the TFT 203, and an electrode formed of a conductive layer in the same layer as the source/drain wiring of the TFT. The lead wiring extends to an end part of a peripheral edge of the substrate and the terminal 106 to which the FPC 107 is later connected is formed. The terminal 106 may be formed in the same layer as the first wiring layer which forms the gate electrode 205.

Following this, a planarization film 210 is formed to cover the TFTs 203 and the lead wiring. Organic materials such as photosensitive acrylic and polyimide are often used as the planarization film. The surface has excellent flatness compared to inorganic insulating materials formed by CVD or the like.

The planarization film 210 is removed in the pixel contact part and a part of the periphery region 270. The section where the conductive layer 209 is exposed by removing the planarization film is once covered with the transparent conductive layer 211. For example, ITO (Indium Tin Oxide) is used as the transparent conductive layer 211. The transparent conductive layer 211 is once covered by the silicon nitride layer 212 and the pixel contact part is reopened. Furthermore, a conductive layer 213 which serves as a pixel electrode is formed above the silicon nitride layer 212. Here, the pixel electrode is formed as a reflective electrode and has a three-layer stacked structure of IZO, Ag and IZO. In the pixel part, an additional capacitor (Cad) 214 is formed by a part overlapping the conductive layer 213 of the transparent conductive layer 211, the silicon nitride layer 212 and the conductive layer 213. On the other hand, the transparent conductive layer 211 is also formed on the surface of the terminal 106. The aim of the transparent conductive layer above the terminal 106 is to arrange the transparent conductive layer as a barrier film to ensure that the exposed part of wiring is not be damaged in a subsequent process.

Although the transparent conductive layer 211 is partly exposed to an etching environment at the time of patterning the pixel electrode (conductive layer 213), the transparent conductive layer 211 has sufficient resistance to etching of the conductive layer 213 due to an annealing process performed between formation of the transparent conductive layer 211 up to formation of the conductive layer 213.

An insulating layer called a bank (rib) 215 and which serves as a partition wall of the sub-pixel 10 is formed after formation of the pixel electrode. That is, the bank 215 partitions the plurality of sub-pixels 10. Similar to the planarization film 210, an organic material such as photosensitive acrylic or polyimide is used as the bank 215. It is preferred that the bank 215 is opened to expose the surface of the pixel electrode as a light emitting region, and an open end thereof has a gentle tapered shape. If the open end has a steep shape, coverage defects are produced in the organic layer to be formed later.

Here, the planarization film 210 and the bank 215 have parts which are brought into contact through an opening 216 which is formed in the silicon nitride layer 212 between them. This is an opening part for pulling out moisture or gas desorbed from the planarization film 210 through the bank 215 through a heat treatment or the like after forming the bank. Moisture or gas which is desorbed here is the same phenomenon as desorbing from the first resin layer 501 or the second resin layer 504 at the time of forming the substrate 101 described above, and by pulling from the planarization film 210 through the opening 216 to the bank 215, it is possible to suppress peeling of the interface between the planarization film 210 and the silicon nitride layer 212.

An organic layer 217 which forms the organic EL layers is stacked and formed after forming the bank 215. Although the organic layer 217 is described as a single layer in FIG. 2, a hole injection layer, a hole transport layer, an electron blocking layer, a light emitting layer, a hole blocking layer, an electron transport layer, and an electron injection layer are stacked and formed in order from the pixel electrode side. These layers may be formed by vapor deposition or by coating formation after dispersion of a solvent. In addition, shown as in FIG. 2, the organic layer 217 may be selectively formed for each light emitting element, or may be formed over the entire surface which covers the display region 260, that is, over the plurality of sub-pixels 10. Several layers including a light emitting layer in the organic layer 217 may be selectively formed for each light emitting element and the remaining layers may be formed across a plurality of sub-pixels 10. In the case where a light emitting layer is formed across a plurality of sub-pixels 10, a structure is possible in which white light emission in all the pixels (all sub-pixels) is obtained and a desired color wavelength part can be extracted by a color filter (not shown in the diagram).

An counter electrode 218 is formed after forming the organic layer 217. Here, since a top emission structure is adopted, it is necessary for the counter electrode 218 to be translucent. Furthermore, the top emission structure refers to a structure in which light is emitted from the counter electrode 218 which is arranged on the substrate 101 interposed by the organic layer 217. Here, as the counter electrode 218, an MgAg film is formed as a thin film to the extent that light emitted from the organic EL layer passes through. The pixel electrode side serves as an anode and the counter electrode side serves as a cathode according to the order of formation of the organic layer 217. The counter electrode 218 is formed from the display region 260 to the cathode contact part 280 arranged in the periphery region 270, is connected to a lower conductive layer 209 by the cathode contact part 280, and is finally extracted to the terminal 106. The counter electrode 218 is supplied with a cathode voltage from the conductive layer 209 at the cathode contact part 280.

A sealing layer 219 is formed after forming the counter electrode. The sealing layer 219 has one of the functions for preventing the entrance of moisture from the exterior into an already formed organic layer and is required high gas barrier properties as a sealing layer. Here, a structure is shown in which a silicon nitride layer 219a, an organic resin 219b and a silicon nitride layer 219c are stacked as a stacked structure including a silicon nitride layer as the sealing layer 219. Furthermore, although not specifically shown in the diagram, an amorphous silicon layer may be arranged between the silicon nitride layer 219a and the organic resin 219b in order to improve adhesion.

Conventionally, it was not possible to improve light emission efficiency in the low current density region where light emission efficiency is low.

In order to solve this problem, one embodiment of the present invention aims to reduce power consumption by improving the light emission efficiency of a display device.

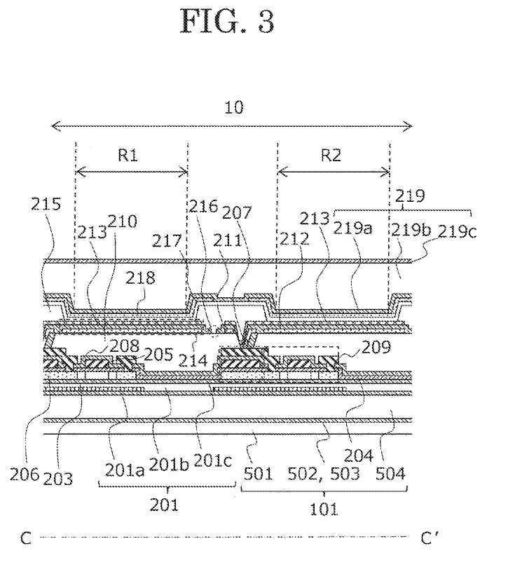

FIG. 3 is a cross-sectional view of a display device according to the first embodiment of the present invention. FIG. 3 schematically shows a cross-sectional structure along the line C-C′ of the display device 100 in FIG. 1.

A sub-pixel 10 of the display device according to the first embodiment of the present invention includes a plurality of light emitting elements. FIG. 3 shows a sub-pixel 10 including light emitting elements R1 and R2 which emit red color. The TFT 203 which is connected to a pixel electrode (conductive layer 213) of the light emitting element R1 and the TFT 203 which is connected to a pixel electrode (conductive layer 213) of the light emitting element R2 are arranged separately. The light emitting element R1 and the light emitting element R2 are driven by independent signals. For example, which light emitting element R1 and R2 is made to emit light is selected according to the gradation of an image signal which is input to a sub-pixel 10 including the light emitting elements R1 and R2. In addition, the same image signal may be simultaneously at the same time to the two TFT's 203 shown in FIG. 3. The sub-pixel 10 which includes light emitting elements G1 and G2 which emit green light and the sub-pixel 10 which includes light emitting elements B1 and B2 which emit blue light are formed in the same way as the sub-pixel 10 including the light emitting elements R1 and R2.

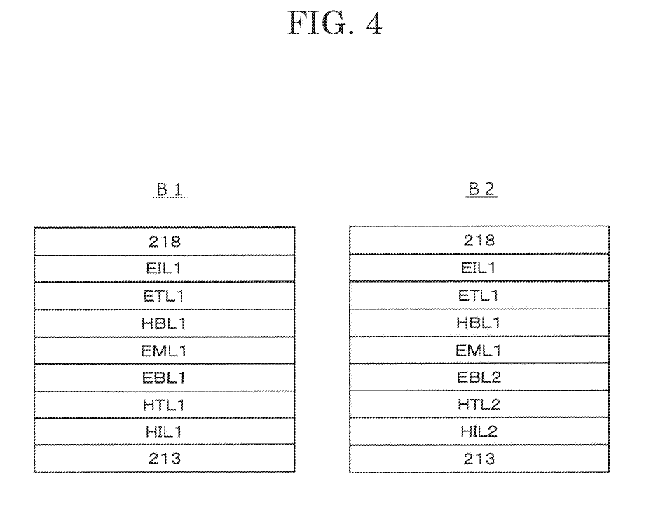

FIG. 4 is a schematic view showing a stacked structure of a light emitting element of the display device according to the first embodiment of the present invention.

As shown in FIG. 4, one of two light emitting elements (for example, B1) included in a sub-pixel 10 includes a hole injection layer HIL1, a hole transport layer HTL1, an electron blocking layer EBL1, a light emitting layer EML1, a hole blocking layer HBL1, an electron transport layer ETL1, an electron injection layer EIL1 and the counter electrode 218 in order from the pixel electrode (conductive layer 213) side.

It is possible to use any one selected from phthalocyanine (H2Pc), copper (II) phthalocyanine (abbreviation: CuPc), vanadyl phthalocyanine (VOPc), 4, 4′, 4″-tris (N, N-diphenylamino) triphenylamine (TDATA), 4,4′, 4″-tris [N-(3-methylphenyl)-N-phenylamino] triphenylamine (MTDATA), 4,4′-bis [N-(4-diphenylaminophenyl)-N-phenylamino]) biphenyl (DPAB), 4,4′-bis (N-{4-[N′-(3-methylphenyl)-N′-phenylamino] phenyl}-N-phenylamino]) biphenyl (DNTPD), 3-[N-(1-naphthyl)-N-(9-phenylcarbazol-3-yl) amino]-9-phenylcarbazole (PCzPCN1), 2,3,6,7,10,11-hexacyano-1,4,5,8,9,12-hexaazatriphenylene (HAT-CN), and polyethylenedioxythiophene-polystyrenesulfonic acid (PEDOT-PSS) and the like as the hole injection layer HIL1.

For example, it is possible to use any one selected from 4,4′-bis [N-(naphthyl)-N-phenyl-amino] biphenyl (α-NPD), N, N′-bis (3-methylphenyl)-(1, 1′ biphenyl)-4, 4′-diamine (TPD), 2-TNATA, -4,4′, 4″-tris (N-(3-methylphenyl) N-phenylamino) triphenylamine (MTDATA), 4,4′-bis [N-(9,9-dimethylfluoren-2-yl)-N-phenylamino] biphenyl (DFLDPBi), and 4,4′-bis [N-(spiro-9,9′-bifluoren-2-yl)-N-phenylamino] biphenyl (BSPB) for the hole transporting layer HTL1.

For example, it is possible to use an aromatic amine derivative, a carbazole derivative, a 9, 10-dihydroacridine derivative, a benzofuran derivative, and a benzothiophene derivative as the material of the electron blocking layer EBL1.

It is possible to form the light emitting layer EML1 by combining a host material and a guest material. When a combination of a host material and a guest material is used, the energy of the host molecule in an excited state moves to the guest molecule and the guest molecule emits energy thereby emitting light. It is possible to use an electron transporting material and a hole transporting material as the host compound. For example, it is possible to use 4-dicyanomethylene-2-methyl-6-(p-dimethylaminostyryl)-4H-pyran (DCM) in a quinolinol metal complex such as Alq₃, a compound doped with pyran derivative such as 4-(dicyanomethylene)-2-t-butyl-6-(1,1,7,7-tetramethylheuoridyl-9-enyl)-4H-pyran (DCJTB), a quinacridone derivative such as 2,3-quinacridone, a coumarin derivative such as 3-(2′-benzothiazole)-7-diethylaminocoumarin or the like, a compound doped with a fused polycyclic aromatic such as perylene to a bis (2-methyl-8-hydroxyquinoline)-4-phenylphenol-aluminum complex, or 4,4′-bis (m-tolylphenylamino) biphenyl (TPD) doped with rubrene or the like, or carbazole compounds such as 4,4′-biscarbazolylbiphenyl (CBP), and 4,4′-bis (9-carbazolyl)-2,2′-dimethylbiphenyl (CDBP) doped with an iridium complex or a platinum complex such as tris-(2-ferririnylpyridine) iridium (Ir (ppy)₃) (green), bis (4,6-di-fluorophenyl)-pyridinate-N, C2) iridium (picolinate) (FIr (pic)) (blue), bis (2-2′-benzothienyl)-(picolinate)-N, C3 iridium (acetylacetonate) (Btp₂Ir (acac)) (red), tris-(picolinate) iridium (Ir (pic)₃) (red), and bis (2-phenylbenzothiozolato-N, C2) iridium (acetylacetonate) (Bt₂Ir (acac)) (yellow).

It is possible to use 4,4′-N, N′-dicarbazole-biphenyl (CBP: 4,4′-N, N′-dicarbozole-biphenyl), or 2,9-dimethyl-4,7-diphenyl-1,10-phenanthroline (BCP: 2,9-dimethyl-4,7-diphenyl-1,10-phenanthroline) as the hole blocking layer HBL1.

It is possible to use a compound of 5 vol % of lithium added to 2,4-bis (4-biphenyl)-6-(4′-(2-pyridyl)-4-diphenyl)-[1,3,5] triazine (MPT: 2,4-(4-biphenyl)-6-(4′-(2-pyridinyl)-4-biphenyl)-[1,3,5] triazine) as the electron transporting layer ETL1.

It is possible to use 8-hydroxyquinoline aluminum (Alq₃), 8-hydroxymethylquinoline aluminum, anthracene, naphthalene, phenanthrene, pyrene, chrysene, perylene, butadiene, coumarin, acridine, stilbene or derivatives of these as the electron injection layer EIL1.

The other of the two light emitting elements (for example B2) of the sub-pixel 10 includes a hole injection layer HIL2, a hole transport layer HTL2, an electron blocking layer EBL2, a light emitting layer EML1, a hole blocking layer HBL1, an electron transport layer ETL1, an electron injection layer EIL1, and the counter electrode 218 stacked and formed in order from the pixel electrode (conductive layer 213) side. That is, the structures of the hole injection layer, the hole transport layer and the electron blocking layer are different between the light emitting element B1 and the light emitting element B2.

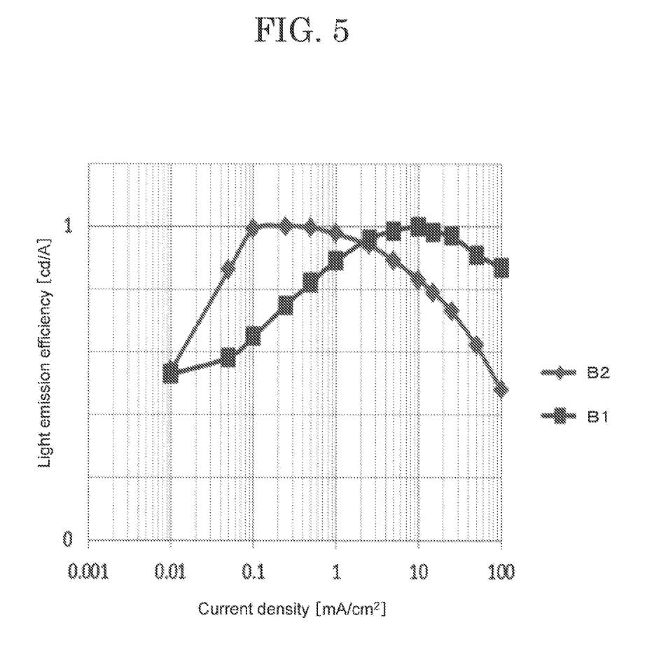

In the first embodiment of the present invention, the magnitude of the current density at the peak of light emission efficiency is different between the light emitting element B1 and the light emitting element B2 shown in FIG. 4. The magnitude of the current density (the peak position of the light emission efficiency in FIG. 5 described later) at the peak of light emission efficiency depends on a carrier balance (balance between injected holes and electrons). Examples of a means for adjusting the carrier balance include selection and adjustment of materials which are doped into each charge injection/transport layer (hole injection layer, hole transport layer, electron injection layer, electron transport layer), and adjustment of a HOMO level and a LUMO level of each charge injection/transport layer, and adjustment of the mobility of each charge injection/transport layer.

Between the light emitting element B1 and the light emitting element B2 shown in FIG. 4, hole injection properties to the light emitting layer of the light emitting element B2 are increased so that hole and electron recombination occurs in a lower current density region than the light emitting element B1. Specifically, the HOMO level of the hole injection layer HIL2 (also called an organic layer located between a pixel electrode and a light emitting layer) of the light emitting element B2 is smaller than the HOMO level of the hole injection layer HIL1 of the light emitting element B1. In this way, the hole injection layer HIL2 has a smaller energy gap difference with the work function of a pixel electrode (conductive layer 213) than the hole injection layer HIL1, and holes are easily injected. In the first embodiment of the present invention, the HOMO level of the hole injection layer HIL2 is 5.5 eV or less, and the HOMO level of the hole injection layer HIL1 is 5.6 eV or more.

In addition, the hole transport layer HTL2 (also called an organic layer located between a pixel electrode and a light emitting layer) has a higher hole mobility in a direction perpendicular to the main surface of the substrate 101 than the hole transporting layer HTL1. In this way, it is easier for the hole transport layer HTL2 to transport holes to the light emitting layer than the hole transport layer HTL1.

FIG. 5 is a graph showing the relationship between light emission efficiency and current density of a light emitting element of the display device according to the first embodiment of the present invention. In FIG. 5, the pixel electrode (conductive layer 213) is ITO and the counter electrode 218 is MgAg. Referring to FIG. 5, the light emission efficiency (cd/A) of the light emitting element B2 of the sub-pixel 10 of the display device according to the first embodiment of the present invention reaches a peak when the current density is approximately 0.1 mA/cm². On the other hand, the light emission efficiency (cd/A) of the light emitting element B1 reaches a peak when the current density is approximately 10 mA/cm². In this way, the magnitude of the current density at the peak of the light emission efficiency deviates between the light emitting element B1 and the light emitting element B2. That is, the magnitudes of the current densities at which the light emission efficiency of the light emitting element B1 and the light emitting element B2 are made to be different from each other, and it is brought into a current density (mA/cm²) region where the peak of the light emission efficiency (cd/A) of the light emitting element B2 is smaller than the peak of the light emission efficiency (cd/A) of the light emitting element B1.

In the display device according to the first embodiment of the present invention, by providing the light emitting element B1 and the light emitting element B2 with the structure described above, since the light emitting element B2 mainly emits light when the current density is small, and the light emitting element B1 emits light when the current density is large, it is possible to maintain light emitting efficiency at a high level even when the current density is small, and it is possible to improve light emission efficiency of the display device and reduce power consumption.

In addition, in the display device according to the first embodiment of the present invention, since the light emitting element B1 and the light emitting element B2 are driven by independent signals, it is possible to select which of the light emitting elements to input a signal to, and it is possible to input different signals to each of the light emitting elements respectively. Therefore, since it is possible to change the presence or absence of an input of signals to a plurality of light emitting elements and make the content of the input signals different according to an image, current density and ON/OFF of a low power consumption mode, it is possible to improve light emission efficiency of a display device and reduce power consumption.

### Second Embodiment

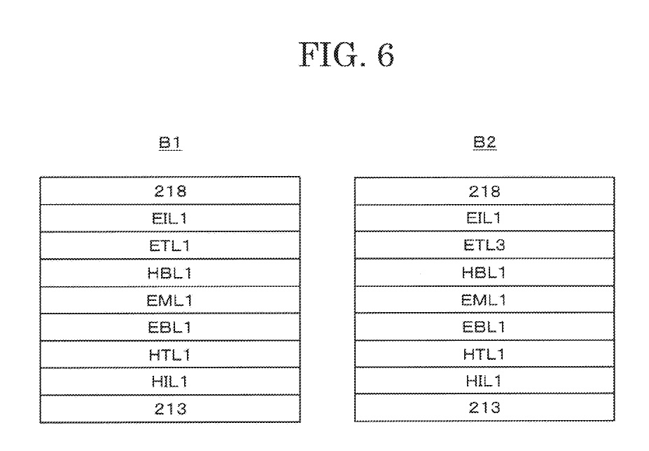

FIG. 6 is a cross sectional view of a light emitting element of a display device according to the second embodiment of the present invention. The light emitting element B1 of the display device according to the second embodiment of the present invention is the same as the light emitting element B1 in the display device according to the first embodiment of the present invention.

The light emitting element B2 of the display device according to the second embodiment of the present invention includes is stacked and formed with a hole injection layer HIL1, a hole transport layer HTL1, an electron blocking layer EBL1, a light emitting layer EML1, a hole blocking layer HBL1, an electron transport layer ETL3, an electron injection layer EIL1 and the counter electrode 218 in order from a pixel electrode (conductive layer 213) side. That is, in the display device according to the second embodiment of the present invention, the structure of the electron transport layer is different between the light emitting element B1 and the light emitting element B2.

The electron transport layer ETL3 of the display device according to the second embodiment of the invention is doped with additives. For example, a lithium complex is added to the electron transport layer ETL3 (also called an organic layer located between a counter electrode and a light emitting layer) by co-evaporation. In other words, the amount of the lithium complex contained in the electron transport layer ETL3 of the light emitting element B2 is higher than in the electron transport layer ETL1 of the light emitting element B1. 8-hydroxyquinolinolato-lithium (Liq) which is one type of lithium quinolate complex is added to the electron transport layer ETL3 of the second embodiment of the present invention.

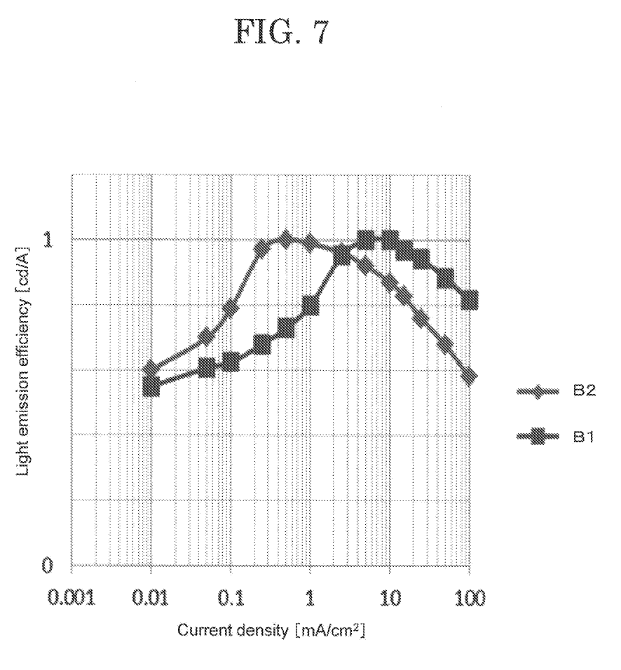

FIG. 7 is a graph showing the relationship between light emission efficiency and current density of the light emitting element of the display device according to the first embodiment of the present invention. In FIG. 7, the pixel electrode (conductive layer 213) is ITO and the counter electrode 218 is MgAg.

The light emission efficiency (cd/A) of the light emitting element B2 of the display device according to the second embodiment of the present invention reaches a peak when the current density is approximately 0.5 mA/cm². On the other hand, the light emission efficiency (cd/A) of the light emitting element B1 reaches a peak when the current density is approximately 7 mA/cm². In this way, the magnitude of the current density at the peak of the light emission efficiency deviates between the light emitting element B1 and the light emitting element B2. That is, the magnitudes of the current densities at which the light emission efficiency of the light emitting element B1 and the light emitting element B2 are made different from each other, and it is brought into a region of a current density (mA/cm²) where the peak of the light emission efficiency (cd/A) of the light emitting element B2 is smaller than the peak of the light emission efficiency (cd/A) of the light emitting element B1.

In the display device according to the second embodiment of the present invention, by providing the light emitting element B1 and the light emitting element B2 with the structure as described above, since the light emitting element B2 mainly emits light when the current density is small, and the light emitting element B1 emits light when the current density is large, it is possible to maintain light emitting efficiency at a high level even when the current density is small, and it is possible to improve light emission efficiency of the display device and reduce power consumption.

### Modified Example 1

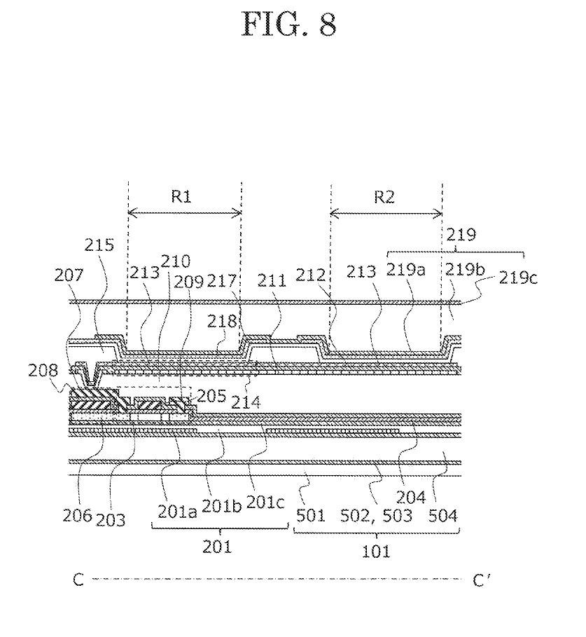

FIG. 8 is showing a cross-sectional view of a display device according to a modified example 1 of the present invention.

In the display device according to the modified example 1 of the present invention, a light emitting element R1 and a light emitting element R2 are driven by a common signal. That is, in the display device according to the modified example 1 of the present invention, a pixel electrode (conductive layer 213) is commonly used for the light emitting element R1 and the light emitting element R2.

Since it is possible to more easily manufacture the display device according to the modified example 1 of the present invention by providing this type of structure, it is possible to save time and labor in the manufacturing process.

### Modified Example 2

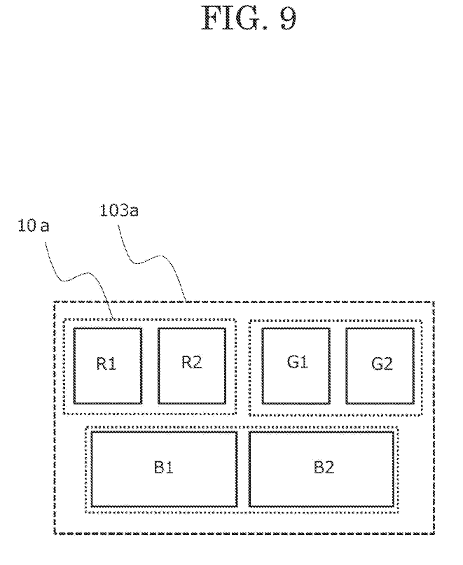

FIG. 9 is a plan view showing a structure of a pixel of a display device according to a modified example 2 of the present invention.

A pixel 103a of the display device according to the modified example 2 of the present invention is formed by arranging a sub-pixel 10a including the light emitting elements R1 and R2 and the sub-pixel 10a including the light emitting elements G1 and G2 in a straight line. The sub-pixel 10a which includes the light emitting elements B1 and B2 is arranged on a straight line different from the straight line on which the sub-pixel 10a which includes the light emitting elements R1 and R2 and the sub-pixel 10a which includes the light emitting elements G1 and G2 are arranged. In addition, the light emitting elements B1 and B2 are formed to include a larger area than the light emitting elements R1 and R2 and the light emitting elements G1 and G2, more specifically, they are formed to include a light emitting region with a large area.

Generally, the light emission efficiency of a blue light emitting element is lower than the light emission efficiency of a red light emitting element and a green light emitting element. The display device according to the modified example 2 of the present invention supplements the low light emission efficiency of the blue light emitting elements B1 and B2 by increasing the areas of the blue light emitting elements B1 and B2. Furthermore, the color of a light emitting element which has an area larger than the light emitting elements of other colors is not limited to blue and may be a color other than blue.

### Modified Example 3

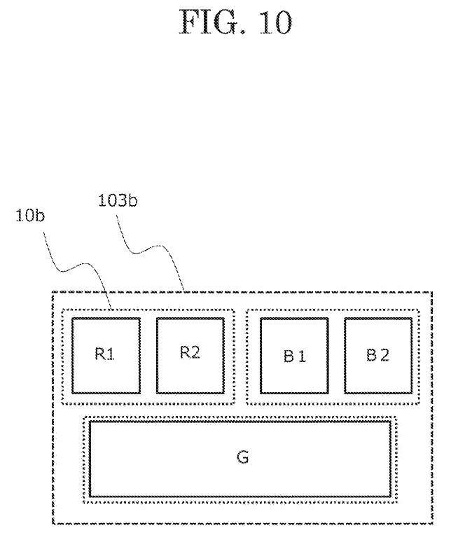

FIG. 10 is a plan view showing a structure of a pixel of a display device according to a modified example 3 of the present invention.

In a pixel 103b of the display device according to the modified example 3 of the present invention, a sub-pixel 10b including the light emitting elements R1 and R2 and a sub-pixel 10b including the light emitting elements B1 and B2 are arranged in a straight line and a light emitting element which emits green light is formed by one light emitting element G. The sub-pixel 10b formed by the light emitting element G is arranged on a straight line different from the straight line on which the sub-pixel 10b which includes the light emitting elements R1 and R2 and the sub-pixel 10b which includes the light emitting elements B1 and B2 are arranged. In addition, the light emitting element G is formed to include a larger area than the light emitting elements R1 and R2 and the light emitting elements B1 and B2.

When the pixel 103b displays white with a predetermined luminosity, all of the red, green, and blue sub-pixels 10b emit light. At this time, the luminosity of the green sub-pixel 10b is higher than the luminosity the red and blue sub-pixels 10b. A suitable structure for light emission with high luminosity is provided to the display device according to the modified example 3 of the present invention by increasing the area of the green light emitting element G which frequently emits light with a higher luminosity than other colors during image display. In addition, since a plurality of light emitting elements are not formed in all the sub-pixels 10b and a sub-pixel 10b comprising one light emitting element is arranged, it is possible to more easily manufacture the display device and save time and labor in the manufacturing process. The sub-pixel 10b comprising one light emitting element is not limited to green and may be a color other than green. In addition, the pixel 103a may be formed having only one sub-pixel 10a arranged with or two or more light emitting elements.

What is claimed is:

1. A display device comprising:
a first pixel emitting a first color and arranged with a first sub-pixel and a second sub-pixel, the first sub-pixel including a first light emitting element and a second light emitting element;
a second pixel emitting a second color different from the first color and next to the first pixel; and
a third pixel emitting a third color different from the first color and the second color and next to the first pixel,
wherein the first light emitting element and the second light emitting element have mutually different magnitude of current density in which light emitting efficiency is at a peak.

2. The display device according to claim 1, wherein the first light emitting element includes a first pixel electrode, a first light emitting layer and a first organic layer located between the first pixel electrode and the first light emitting layer, the second light emitting element includes a second pixel electrode, a second light emitting layer and a second organic layer located between the second pixel electrode and the second light emitting layer, and a HOMO level of the second organic layer is smaller than a HOMO level of the first organic layer.

3. The display device according to claim 2, wherein the first organic layer is a first hole injection layer of the first light emitting element, and the second organic layer is a second hole injection layer of the second light emitting element.

4. The display device according to claim 3, wherein the first pixel is arranged above a substrate, a first hole transport layer is located between the first hole injection layer and the first light emitting layer, a second hole transport layer is located between the second hole injection layer and the second light emitting layer, and the second hole transport layer has a larger hole mobility in a perpendicular direction with respect to a main surface of the substrate than the first hole transport layer.

5. The display device according to claim 1, wherein the first pixel is arranged above a substrate, the first light emitting element includes a first pixel electrode, a first light emitting layer and a first organic layer located between the first pixel electrode and the first light emitting layer, the second light emitting element includes a second pixel electrode, a second light emitting layer and a second organic layer located between the second pixel electrode and the second light emitting layer, and the second organic layer has a larger hole mobility in a perpendicular direction with respect to a main surface of the substrate than the first organic layer.

6. The display device according to claim 5, wherein the first organic layer is a first hole transport layer of the first light emitting element, and the second organic layer is a second hole transport layer of the second light emitting element.

7. The display device according to claim 1, wherein the first light emitting element includes a first pixel electrode, a first light emitting layer, a first counter electrode, and a third organic layer located between the first counter electrode and the first light emitting layer, the second light emitting element includes a second pixel electrode, a second light emitting layer, a second counter electrode and a fourth organic layer located between the second counter electrode and the second light emitting layer, and the fourth organic layer has a greater content amount of a lithium complex than the third organic layer.

8. The display device according to claim 7, wherein the third organic layer is a first electron transport layer of the first light emitting element, and the fourth organic layer is a second electron transport layer of the second light emitting element.

9. The display device according to claim 8, wherein the lithium complex is Liq.

10. The display device according to claim 9, wherein the first light emitting element is input with a signal independent from a signal input to the second light emitting element.

11. The display device according to claim 9, wherein the first light emitting element and the second light emitting element are input with a common signal.

12. The display device according to claim 11, wherein the second sub-pixel includes a third light emitting element.

13. The display device according to claim 12, wherein a light emitting region of the third light emitting element is larger than a light emitting region of the first light emitting element and the second light emitting element.

14. The display device according to claim 11, wherein the first pixel is arranged with a first sub-pixel including the first light emitting element and the second light emitting element emitting a first color, a second sub-pixel including the third light emitting element and the fourth light emitting element emitting a second color, and a third sub-pixel including a fifth light emitting element and a sixth light emitting element emitting a third color, the first sub-pixel and the second sub-pixel are arranged in a straight line, the third sub-pixel is arranged at a different position to the straight line where the first sub-pixel and the second sub-pixel are arranged, and each light emitting region of the fifth light emitting element and the sixth light emitting element are larger than each light emitting region of the first to fourth light emitting elements.

15. The display device according to claim 14, wherein the third color is blue.

16. The display device according to claim 11, wherein the first pixel is arranged with a first sub-pixel including the first light emitting element and the second light emitting element emitting a first color, a second sub-pixel including the third light emitting element and the fourth light emitting element emitting a second color, and a third sub-pixel including a fifth light emitting element and a sixth light emitting element emitting a third color, the first sub-pixel and the second sub-pixel are arranged in a straight line, the third sub-pixel is arranged at a different position to the straight line where the first sub-pixel and the second sub-pixel are arranged, and each light emitting region of the fifth light emitting element is larger than each light emitting region of the first to fourth light emitting elements.

17. The display device according to claim 1, wherein
the first color is red.

18. The display device according to claim 1, wherein
the first color is green.

19. The display device according to claim 1, wherein
the first color is blue.
